(19) United States
(12) Patent Application Publication
(10) Pub. No.: US 2025/0147410 A1
(43) Pub. Date: May 8, 2025

(54) RETICLE POD WITH AIR FLOW MANAGEMENT FEATURE

(71) Applicant: ENTEGRIS, INC., Billerica, MA (US)

(72) Inventors: Russ V. Raschke, Chanhassen, MN (US); Huaping Wang, Eden Prairie, MN (US)

(21) Appl. No.: 18/942,306

(22) Filed: Nov. 8, 2024

Related U.S. Application Data
(60) Provisional application No. 63/547,830, filed on Nov. 8, 2023.

(51) Int. Cl. G03F 1/66

(52) U.S. Cl. CPC G03F 1/66

(57) ABSTRACT

Substrate containers include a deformable surface configured to deflect into an internal space so as to reduce the volume of said internal space when the reticle pod is opened. The deformable surface can be a filter, for example a filter supported by a deformable member, a filter including a deformable member, a filter that is retained under tension in the substrate container, or a filter disposed on a deformable member.

### FIELD

This disclosure is directed to substrate containers including features for airflow management during opening.

### BACKGROUND

Substrates that are processed, for example through extreme ultraviolet (EUV) photolithography processes, must be kept clean to prevent defects and improve process yield. The substrate containers used in EUV processing can be configured to form a seal or other air barrier when the reticle pod is closed.

### SUMMARY

This disclosure is directed to substrate containers including features for airflow management during opening.

By reducing a volume within the reticle pod during the opening of the substrate container, pumping effects occurring due to sealing of the reticle pod can be suppressed. As a result, a speed of air entering the reticle pod during opening can be reduced. Reducing the speed of air entering the reticle pod can reduce the extent of contamination, such as particulate matter, that is brought into contact with the substrate within the container.

In an embodiment, an article includes an inner pod of a reticle pod. The inner pod includes a cover and a baseplate, wherein at least one of the cover and the baseplate include a volume adjustment surface configured to be deflected into an internal space defined by the inner pod by a maximum deflection of at least 0.5 mm when the cover and the baseplate are separated.

In an embodiment, the deflectable surface is a filter. In an embodiment, the filter includes expanded polytetrafluoroethylene. In an embodiment, the filter includes a deflectable scrim. In an embodiment, the article further includes a filter support configured to be deflected when the cover and the baseplate are separated. In an embodiment, the filter is secured over a filter opening by a retainer, and the filter is in tension when the retainer secures the filter. In an embodiment, the filter is configured to deflect at a perimeter when the cover and the baseplate are separated such that a central portion of the filter projects into the internal space.

In an embodiment, a reticle pod includes an outer pod including a pod dome and a pod door, and the article as described herein.

In an embodiment, a method of opening an inner pod of a reticle pod includes deflecting a volume adjustment surface into an internal space defined by a cover and a baseplate of the inner pod by a maximum deflection of at least 0.5 mm when the cover and the baseplate are separated.

In an embodiment, the volume adjustment surface is a filter. In an embodiment, the filter includes expanded polytetrafluoroethylene. In an embodiment, the filter includes a deflectable scrim. In an embodiment, the inner pod further includes a filter support configured to be deflected when the cover and the baseplate are separated. In an embodiment, the filter is secured over a filter opening by a retainer, and the filter is in tension when the retainer secures the filter. In an embodiment, the volume adjustment surface includes a filter retainer configured to deflect at a perimeter when the cover and the baseplate are separated such that a filter projects into the internal space.

In an embodiment, an article includes a reticle pod. The reticle pod includes a cover and a baseplate forming an internal space in the reticle pod. At least one of the cover and the baseplate include a volume adjustment filter capable of deforming during separation of the cover and the base plate such that a peak pressure differential in the internal space during separation of the cover and the baseplate is reduced by between 15% and 55% in comparison to a reticle pod without the volume adjustment filter.

In an embodiment, the reticle pod further comprises a pod dome and a pod door. In an embodiment, the volume adjustment filter includes a deflectable scrim. In an embodiment, the volume adjustment filter comprises a filter support, the filter support configured to be deflected during separation of the cover and the baseplate. In an embodiment, the volume adjustment filter is secured over a filter opening by a retainer, and the volume adjustment filter is in tension when the retainer secures the volume adjustment filter.

### BRIEF DESCRIPTION OF THE DRAWINGS

FIG. 1 shows a reticle pod according to an embodiment.

FIG. 2 shows a sectional view of a cover of an inner pod of reticle pod according to an embodiment.

FIG. 3 shows a sectional view of a cover of an inner pod of a reticle pod according to an embodiment.

FIG. 4 shows a sectional view of a cover of an inner pod of a reticle pod according to an embodiment.

FIG. 5 shows a filter support according to an embodiment.

FIG. 6 shows a filter according to an embodiment.

FIG. 7 shows a method of opening a substrate container.

### DETAILED DESCRIPTION

This disclosure is directed to substrate containers including features for airflow management during opening.

As used herein, “volume adjustment surface” is a surface provided in a movable manner, such that the surface can move, for example by deflection of the surface or of a member joined to the surface, in response to forces such as vacuum or pumping forces when a reticle pod is opened, such that the internal volume of the reticle pod can be changed by the movement of the volume adjustment surface. The volume adjustment surface can be capable of deflection, provided on a member capable of deflection, or the like.

As used herein, “maximum deflection” means the distance between a resting position and a deflected position of the point on a volume adjustment surface having the greatest distance between the resting position and the deflected position as measured during a typical opening of a reticle pod by separation of a cover from the corresponding baseplate. As an illustrative example, the maximum deflection of a dome-shaped volume adjustment surface can be measured by the distance between the peak of the dome in the resting position and the peak of the dome in the deflected position.

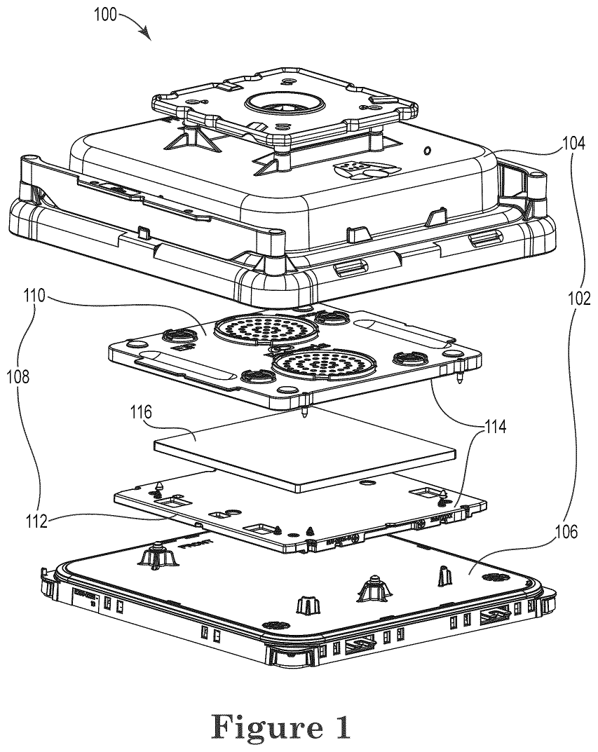

FIG. 1 shows a reticle pod according to an embodiment. Reticle pod 100 includes outer pod 102. Outer pod 102 includes pod dome 104 and pod door 106. Reticle pod 100 further includes inner pod 108. Inner pod 108 includes cover 110 and baseplate 112. Each of cover 110 and baseplate 112 include corresponding sealing surfaces 114. Reticle pod 100 can accommodate reticle 116.

Outer pod 102 forms an exterior of reticle pod 100 when reticle pod 100 is fully assembled. Outer pod 102 is configured to form an internal space capable of accommodating inner pod 108.

Outer pod 102 can be formed of pod dome 104 and pod door 106. Pod dome 104 and pod door 106 can be configured to be joined to one another, for example using a latching mechanism (not shown). The pod dome 104 and pod door 106 can be configured such that the inner pod 108 is retained within the internal space defined by the pod dome 104 and pod door 106.

Inner pod 108 is a pod configured to accommodate the reticle 116. Inner pod 108 includes the cover 110 and the baseplate 112. The inner pod 108 is configured such that it can fit within the internal space of outer pod 102.

Sealing surfaces 114 are corresponding surfaces provided on each of cover 110 and baseplate 112. Sealing surfaces 114 are configured to face one another when the cover 110 and baseplate 112 are positioned together to form the inner pod 108 surrounding a substrate. In an embodiment, sealing surfaces 114 contact one another at least over a portion thereof when cover 110 and baseplate 112 are assembled together. In an embodiment, sealing surfaces 114 can be spaced apart by a distance, the distance being small enough that a pressure differential can exist between the interior of the inner pod 108 and the exterior thereof. When sealing surfaces 114 are separated during opening of the inner pod 108, a pumping effect can occur due to the sealing surfaces restricting flow into the interior of the inner pod 108 compared to the change in internal volume thereof during the opening process.

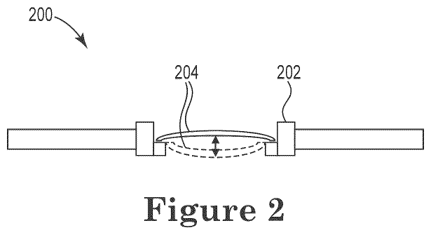

FIG. 2 shows a sectional view of a cover of an inner pod of reticle pod according to an embodiment. Cover 200 is a cover of an inner pod of a substrate container, such as cover 110 of inner pod 108 as described above and shown in FIG. 1. As shown in FIG. 2, cover 200 includes filter opening 202 accommodating a filter 204.

Filter opening 202 is an opening configured to be covered by filter 204. Filter opening 202 is configured to allow flow of gas into or out of the inner pod including cover 200 under some conditions.

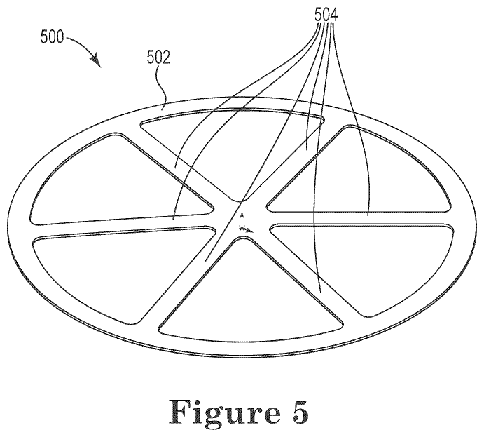

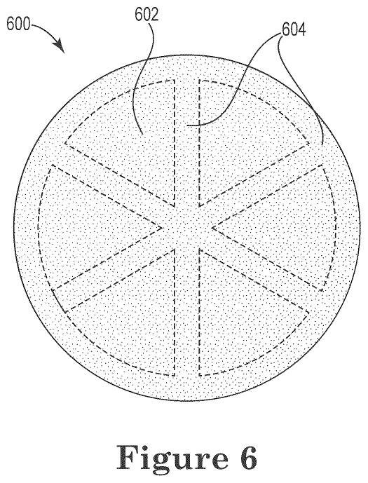

Filter 204 is a filter configured to deform in response to vacuum force when the cover 200 is separated from a corresponding baseplate. Filter 204 can be used as a volume adjustment surface in the reticle pod including cover 200. In an embodiment, the filter 204 can have a domed shape. In an embodiment, the filter 204 can be configured such that the dome is concave relative to an inner surface of the cover 200 when in a resting position, as shown in solid lines in FIG. 2. In an embodiment, the filter 204 can be configured such that the dome is convex relative to an inner surface of the cover 200 when in a deformed position as shown in the dashed lines in FIG. 2, for example when the filter 200 has been subjected to vacuum force. This exposure to vacuum force can occur, for example, when the cover 200 is separated from the corresponding baseplate. In an embodiment, a distance between at least one point on the filter 204 when in the resting position and said point on the filter 204 when in the deformed position can be 0.5 millimeters (mm) or greater. The filter 204 can be positioned and/or configured such that deformation of the filter 204 would not result in contact or interference with a reticle contained within the inner pod. The filter 204 can include any suitable filter material for use in a substrate container, such as an expanded polytetrafluoroethylene, or the like. In an embodiment, filter 204 can be retained in filter opening by a retainer, such as filter support 500 described below and shown in FIG. 5. In an embodiment, filer 204 includes a scrim, for example as shown in FIG. 6 and described below. In an embodiment, filter 204 can have a shape selected to improve the compliance of filter 204 and its ability to deform so as to extend into the internal space, such as, as a non-limiting example, linear or radial pleating.

While FIG. 2 shows filter opening 202 and filter 204 on cover 200, it is understood that a filter opening 202 and filter 204 as shown in FIG. 2 could instead be provided on a baseplate, such as baseplate 112 of inner pod 108 instead, with the filter opening 202 and filter 204 positioned so as to avoid a substrate contained within the reticle pod even when filter opening 202 and filter 204 are provided on the baseplate.

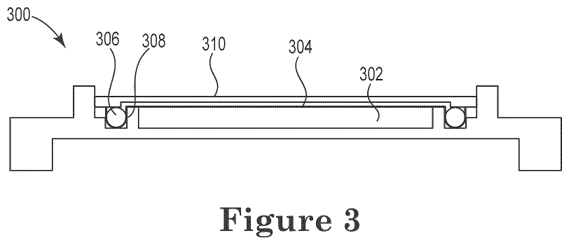

FIG. 3 shows a sectional view of a cover of an inner pod of a reticle pod according to an embodiment. Cover 300 includes a filter opening 302, a filter membrane 304, and a membrane retainer 306. Filter opening 302 can be defined by features providing a retention surface 308.

Filter opening 302 is an opening configured to be covered by filter membrane 304. Filter opening 302 is configured to allow flow of gas through filter membrane 304 and into or out of the inner pod including cover 300 under some conditions. Filter opening 302 can have any suitable size, shape, and position. In an embodiment, filter opening 302 is circular in shape. In an embodiment, filter opening 302 is positioned such that filter membrane 304 would not interfere with any other structures inside of the container formed by cover 300 and the corresponding baseplate, or a substrate stored therein such as a reticle.

Filter membrane 304 is stretched over the filter opening 302. Filter membrane 304 can be a resilient membrane capable of stretching or deformation when subjected to force, for example due to pumping effects occurring when opening an inner pod including the cover 300. Filter membrane 304 can be used as a volume adjusting surface for the reticle pod including cover 300. Filter membrane 304 can include features to improve the compliance of filter membrane 304, with non-limiting examples including linear or radial pleating, such that the filter membrane is capable of serving as the volume adjustment surface. In an embodiment, filter membrane 304 can be configured such that the filter membrane 304 expresses a maximum deflection of at least 0.5 mm when the cover 300 is separated from a corresponding baseplate. In an embodiment, filter membrane 304 is configured to return to a resting position when force used to deflect filter membrane 304 has been removed. In an embodiment, the return to the resting position can be supported by the tension of filter membrane 304 provided by its retention over filter opening 302 by the membrane retainer 306.

Filter membrane 304 can be retained over filter opening 302 by membrane retainer 306. Membrane retainer 306 can be configured to maintain the filter membrane 304 under tension. Membrane retainer 306 can have any suitable shape and size for retaining the filter membrane 304 over the filter opening 302. In an embodiment, retainer 306 is a ring configured to surround the filter opening 302. In an embodiment, the retainer 306 can be an O-ring. In an embodiment, the membrane retainer 306 can be configured to be received in a groove formed at filter opening 302. In an embodiment, the membrane retainer 306 is formed of a resilient material, with non-limiting examples including fluoroelastomers. In an embodiment, the membrane retainer 306 can contact a retention surface 308 surrounding filter opening 302 such that membrane retainer 306 is kept in place when filter membrane 304 is in tension. In an embodiment, retention surface 308 is a flat surface. In an embodiment, retention surface 308 is or includes a groove. In an embodiment, a filter cover 310 can be provided, further contacting and securing the membrane retainer 306.

While FIG. 3 shows filter opening 302 and filter membrane 304 on cover 300, it is understood that a filter opening 302 and filter membrane 304 as shown in FIG. 3 could instead be provided on a baseplate, such as baseplate 112 of inner pod 108 instead, with the filter opening 302 and filter membrane 304 positioned so as to avoid a substrate contained within the reticle pod even when filter opening 302 and filter membrane 304 are provided on the baseplate.

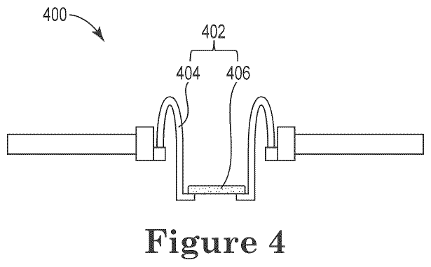

FIG. 4 shows a sectional view of a cover of an inner pod of a reticle pod according to an embodiment. Cover 400 includes a filter assembly 402, including resilient section 404 and filter 406.

Filter assembly 402 is configured to provide a volume adjustment surface for cover 400. Filter assembly 402 includes resilient section 404 and filter 406. The filter assembly 402 can provide a maximum deflection of at least 0.5 mm for at least a portion of the filter 406, such that the filter 406 serves as the volume adjustment surface within the reticle pod including cover 400.

Resilient section 404 is configured to support the filter 406. Resilient section 404 can be further configured such that the extent to which the resilient section 404 and supported filter 406 extend into the interior space of the reticle pod including cover 400 can be varied. In an embodiment, resilient section 404 includes one or more pleats, folds, bends, or any other suitable feature allowing the portion of resilient section 404 retaining the filter 406 to be moved towards an interior space defined by cover 400 and a corresponding baseplate. Resilient section 404 can be made of any suitable resilient material capable of deformation under force and return to at or near its original shape following removal of the force. A non-limiting example of a suitable resilient material is a fluoroelastomer. The material can be selected to allow the desired deformation characteristics for resilient section 404. The material can be selected further based on other characteristics relevant to use in reticle pods, such as off-gassing or other cleanliness factors.

Filter 406 is a filter configured to be retained in resilient section 404. The filter 406 can be any suitable filter, such as an expanded polytetrafluoroethylene filter. In an embodiment, filter 406 can be configured to be deflectable, for example using a filter retainer such as filter retainer 500 described below and shown in FIG. 5 or a filter such as filter 600 including a deflectable scrim 604 as shown in FIG. 6 and described below.

While FIG. 4 shows filter assembly 402, resilient section 404, and filter 406 on cover 400, it is understood that filter assembly 402, resilient section 404, and filter 406 as shown in FIG. 3 could instead be provided on a baseplate, such as baseplate 112 of inner pod 108 instead, with the filter assembly 402, resilient section 404, and filter 406 positioned so as to avoid a substrate contained within the reticle pod even when filter opening 302 and filter membrane 304 are provided on the baseplate.

FIG. 5 shows a filter support according to an embodiment. Filter support 500 is configured to support a filter such that said filter can be used as a volume adjustment surface within a substrate container. Filter support 500 includes a perimeter 502 and a plurality of beams 504. Filter support 500 can be made of a material capable of deflection and return to a resting state, for example a polyethylene material such as linear low-density polyethylene. Filter support 500 can be shaped to allow the filter support to be deformed such that the filter used with filter support 500 can extend into the interior space of the inner pod when subject to force. A suitable configuration is shown in the non-limiting example of FIG. 5, wherein there is a solid perimeter 502, with a plurality of beams 504 each extending to a center of the filter support 500. The beams 504 can be radially distributed about perimeter 502. The thickness, distribution, and/or number of beams 504 can be any suitable values or combination thereof for achieving the desired deflection and filter retention properties, and can vary based on the size of the filter and filter opening that filter support 500 is to be used with, the filter material for such a filter, the forces experienced by the filter or that result during opening of the inner pod, and any other such suitable factors. In other embodiments, filter 500 can have any other suitable shape, such as a grid, radial spokes without a perimeter, shapes suitable for non-circular filters, and the like so long as filter support 500 allows for sufficient deformation to allow the supported filter to operate as a volume adjustment surface in the substrate container.

FIG. 6 shows a filter according to an embodiment. Filter 600 includes filter material 602 and scrim 604. Filter 600 can be used as a volume adjustment surface within a substrate container. In an embodiment, filter 600 can have a maximum deflection of at least 0.5 mm. Filter material 602 can be formed around scrim 604. Filter material 602 can be any suitable filter material, such as, as a non-limiting example, expanded polytetrafluoroethylene. Scrim 604 is configured to support filter material 602. Scrim 604 can have any suitable shape and size to support filter material 602 and to provide the desired deflection characteristics to filter 600, for example having a circular perimeter and a plurality of spokes meeting at a central portion of the scrim 604. In embodiments, scrim 604 can have any other suitable shape, such as a grid, radial spokes without a perimeter portion, shapes suitable for supporting non-circular filters, and the like. Scrim 604 can be made of any suitable material, with a non-limiting example being a polyethylene material such as linear low-density polyethylene. The material can be selected at least in part to achieve suitable deflection characteristics for filter 600, in combination with the shape of the scrim 604, the thicknesses of elements thereof, and the like. In an embodiment, scrim 604 can be configured to return to a resting position when force used to deflect scrim 604 has been removed.

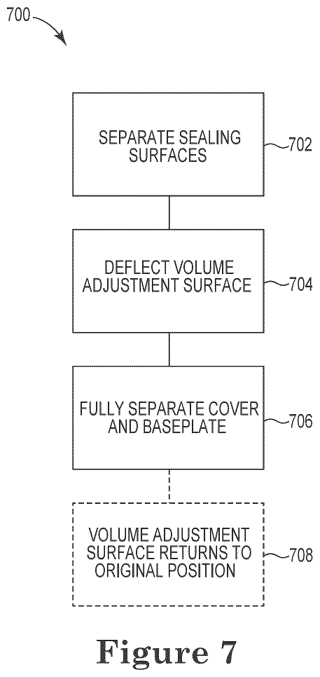

FIG. 7 shows a method of opening a substrate container. Method 700 includes separating sealing surfaces at 702, deflecting a volume adjustment surface so as to reduce the internal volume of the reticle pod at 704, and fully separating the cover from the baseplate at 706. In an embodiment, method 700 further includes the volume adjustment surface returning to its original position at 708.

Sealing surfaces of the reticle pod are separated at 702. In an embodiment, at least portions of the sealing surfaces are in contact with one another. In an embodiment, the sealing surfaces of the reticle pod are in close proximity such that a pressure different can exist between the interior and the exterior of the reticle pod. When the sealing surfaces of the reticle pod are separated at 702, the internal volume of the reticle pod is increased as the distance between the cover and the baseplate increases. This increase in internal volume can occur while the distance between the sealing surfaces is small enough to restrict flow into the reticle pod, thereby causing a relatively reduced pressure within the reticle pod.

A volume adjustment surface can be deflected to reduce the internal volume at 704. In an embodiment, the volume adjustment surface is deflected at 704 by the reduction in pressure within the reticle pod. In an embodiment, the volume adjustment surface can be actuated by any other suitable means, such as mechanical engagement by a tool supporting the reticle pod, or the like. The volume adjustment surface is deflected inwards into the reticle pod, thereby reducing the internal volume of the reticle pod. By deflecting into the pod so as to reduce the internal volume, the extent of pressure reduction within the pod can thereby be reduced, keeping the pressure within the reticle pod closer to the ambient pressure. By keeping the pressure within the reticle pod closer to the ambient pressure, ambient gas entering the reticle pod as the reticle pod opens can be reduced, thereby reducing the likelihood and/or extent of particulate material entering the reticle pod.

The reticle pod continues to be opened until the reticle pod is fully opened at 706. As the reticle pod opens, the space between the sealing surfaces increases, and ambient gas can enter the reticle pod. The pressure difference drawing ambient gas into the reticle pod can be reduced by the deflection of the volume adjustment surface at 704 as described above. When the reticle pod is fully opened at 706, the pressure of the interior of the reticle pod and the ambient pressure are equalized.

The volume adjustment surface returns to its original position at 708. The volume adjustment surface can return to its original position at 708 based on the manner in which the volume adjustment surface was actuated, for example using resilience of parts used in the volume adjustment surface and/or any other actuator used when deflecting the volume adjustment surface at 708. In an embodiment, the volume adjustment surface returns to its original position at 708 based entirely on the resilience of the parts used in the volume adjustment surface.

One manner in which the reduction of pumping effect from the opening of the reticle pod can be characterized is by the maximum pressure differential between the interior and exterior of the reticle pod during a pod opening process. One such test for determining the maximum pressure differential during the opening process can be performed by using a clean reticle pod, not containing a reticle, and placing the reticle pod into a standard cycler for reticle pods. A differential pressure sensor can be installed with one end at ambient atmospheric pressure, and the other passing into the reticle pod through a standard through hole, such as a reticle clamp opening, provided in the reticle cover. At ambient atmospheric pressure, the cycler can open the reticle pod at an opening speed of 12 millimeters (mm) per second by lowering a baseplate of the reticle pod away from the cover of the reticle pod. Under such testing, reticle pods according to standard designs resulted in peak differential pressures of 282.9 Pa and 268.4 Pa, whereas designs including modification to allow deflection of the filter by reducing support to increase filter deflection by 2 mm, removal of a central filter support from the current design, and combining the removal of the central filter support with a softening of the filter had peak differential pressures of 225.0 Pa, 162.5 Pa, and 134.0 Pa, respectively. Accordingly, increasing the compliance of the filter compared to standard reticle pod designs resulted in peak differential pressures being reduced by 15% to 55%.

### Aspects

It is understood that any of aspects 1-8 can be combined with any of aspects 9-15 or 16-20. It is understood that any of aspects 9-15 can be combined with any of aspects 16-20.

Aspect 1. An article, comprising an inner pod of a reticle pod, the inner pod comprising a cover and a baseplate, wherein at least one of the cover and the baseplate include a volume adjustment surface configured to be deflected into an internal space defined by the inner pod by a maximum deflection of at least 0.5 mm when the cover and the baseplate are separated.

Aspect 2. The article according to aspect 1, wherein the deflectable surface is a filter.

Aspect 3. The article according to aspect 2, wherein the filter includes expanded polytetrafluoroethylene.

Aspect 4. The article according to any of aspect 2-3, wherein the filter includes a deflectable scrim.

Aspect 5. The article according to any of aspects 2-4, comprising a filter support configured to be deflected when the cover and the baseplate are separated.

Aspect 6. The article according to any of aspects 2-5, wherein the filter is secured over a filter opening by a retainer, and the filter is in tension when the retainer secures the filter.

Aspect 7. The article according to any of aspects 2-6, wherein the filter is configured to deflect at a perimeter when the cover and the baseplate are separated such that a central portion of the filter projects into the internal space.

Aspect 8. A reticle pod comprising an outer pod including a pod dome and a pod door, and the article according to any of aspects 1-7.

Aspect 9. A method of opening an inner pod of a reticle pod, comprising deflecting a volume adjustment surface into an internal space defined by a cover and a baseplate of the inner pod by a maximum deflection of at least 0.5 mm when the cover and the baseplate are separated.

Aspect 10. The method according to aspect 9, wherein the volume adjustment surface is a filter.

Aspect 11. The method according to aspect 10, wherein the filter includes expanded polytetrafluoroethylene.

Aspect 12. The method according to any of aspects 10-11, wherein the filter includes a deflectable scrim.

Aspect 13. The method according to any of aspects 10-12, wherein the inner pod further comprises a filter support configured to be deflected when the cover and the baseplate are separated.

Aspect 14. The method according to any of aspects 10-13, wherein the filter is secured over a filter opening by a retainer, and the filter is in tension when the retainer secures the filter.

Aspect 15. The method according to any of aspects 9-14, wherein the filter is configured to deflect at a perimeter when the cover and the baseplate are separated such that a central portion of the filter projects into the internal space.

Aspect 16. An article, comprising a reticle pod, the reticle pod having a cover and a baseplate forming an internal space in the reticle pod, wherein at least one of the cover and the baseplate include a volume adjustment filter capable of deforming during separation of the cover and the base plate such that a peak pressure differential in the internal space during separation of the cover and the baseplate is reduced by between 15% and 55% in comparison to a reticle pod without the volume adjustment filter.

Aspect 17. The article according to aspect 16, wherein the reticle pod further comprises a pod dome and a pod door.

Aspect 18. The article according to aspect 16 or 17, wherein the volume adjustment filter includes a deflectable scrim.

Aspect 19. The article according to any of aspects 16-18 wherein the volume adjustment filter comprises a filter support, the filter support configured to be deflected during separation of the cover and the baseplate.

Aspect 20. The article according any of aspects 16-19, wherein the volume adjustment filter is secured over a filter opening by a retainer, and the volume adjustment filter is in tension when the retainer secures the volume adjustment filter.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article, comprising an inner pod of a reticle pod, the inner pod comprising a cover and a baseplate, wherein at least one of the cover and the baseplate include a volume adjustment surface configured to be deflected into an internal space defined by the inner pod by a maximum deflection of at least 0.5 mm when the cover and the baseplate are separated.

2. The article of claim 1, wherein the deflectable surface is a filter.

3. The article of claim 2, wherein the filter includes expanded polytetrafluoroethylene.

4. The article of claim 2, wherein the filter includes a deflectable scrim.

5. The article of claim 2, comprising a filter support configured to be deflected when the cover and the baseplate are separated.

6. The article of claim 2, wherein the filter is secured over a filter opening by a retainer, and the filter is in tension when the retainer secures the filter.

7. The article of claim 2, wherein the filter is configured to deflect at a perimeter when the cover and the baseplate are separated such that a central portion of the filter projects into the internal space.

8. A reticle pod comprising an outer pod including a pod dome and a pod door, and the article of claim 1.

9. A method of opening an inner pod of a reticle pod, comprising deflecting a volume adjustment surface into an internal space defined by a cover and a baseplate of the inner pod by a maximum deflection of at least 0.5 mm when the cover and the baseplate are separated.

10. The method of claim 9, wherein the volume adjustment surface is a filter.

11. The method of claim 10, wherein the filter includes expanded polytetrafluoroethylene.

12. The method of claim 10, wherein the filter includes a deflectable scrim.

13. The method of claim 10, wherein the inner pod further comprises a filter support configured to be deflected when the cover and the baseplate are separated.

14. The method of claim 10, wherein the filter is secured over a filter opening by a retainer, and the filter is in tension when the retainer secures the filter.

15. The method of claim 9, wherein the volume adjustment surface includes a filter retainer configured to deflect at a perimeter when the cover and the baseplate are separated such that a filter projects into the internal space.

16. An article, comprising a reticle pod, the reticle pod having a cover and a baseplate forming an internal space in the reticle pod, wherein at least one of the cover and the baseplate include a volume adjustment filter capable of deforming during separation of the cover and the base plate such that a peak pressure differential in the internal space during separation of the cover and the baseplate is reduced by between 15% and 55% in comparison to a reticle pod without the volume adjustment filter.

17. The article of claim 16, wherein the reticle pod further comprises a pod dome and a pod door.

18. The article of claim 16, wherein the volume adjustment filter includes a deflectable scrim.

19. The article of claim 16, wherein the volume adjustment filter comprises a filter support, the filter support configured to be deflected during separation of the cover and the baseplate.

20. The article of claim 16, wherein the volume adjustment filter is secured over a filter opening by a retainer, and the volume adjustment filter is in tension when the retainer secures the volume adjustment filter.
